(19) United States
(12) Patent Application Publication
(10) Pub. No.: US 2025/0247099 A1
(43) Pub. Date: Jul. 31, 2025

(54) SUPPRESSING SPURIOUS TONES RESULTING FROM THE REQUANTIZATION OF THE ACCUMULATED QUANTIZATION ERROR WHEN PERFORMING FRACTIONAL FREQUENCY DIVISION

(71) Applicant: University College Dublin, Dublin 4 (IE)

(72) Inventors: Xu WANG, Dublin (IE); Michael Peter KENNEDY, Dublin (IE)

(21) Appl. No.: 19/043,225

(22) Filed: Jan. 31, 2025

Related U.S. Application Data
(60) Provisional application No. 63/627,763, filed on Jan. 31, 2024.

(51) Int. Cl. H03K 21/08; H03K 5/00; H03K 5/1252

(52) U.S. Cl. CPC H03K 21/08; H03K 5/1252; H03K 2005/00058

(57) ABSTRACT

A fractional frequency divider configured to suppress spurious tones resulting from requantization of an accumulated quantization error has a multi-modulus divider (MMD) and one or more digital-to-time converters (DTCs). Each DTC includes a gain and/or digital predistortion, a dithered requantizer having a multibit input signa, a multibit output signal, and a multibit digitally-controllable delay (DCD). The quantized time delay between the input and output of the DTC is determined by the input from the MMD controller, the gain/digital predistortion and the requantizer. The MMD controller provides an input to the DTC that is proportional to the accumulated time quantization error introduced by the MMD controller, the gain/digital predistortion scales by a gain factor to produce a signal (a[k]) that is combined with a discrete-valued dither signal in the dithered requantizer to provide the control input of the DCD.

### CROSS-REFERENCE TO RELATED APPLICATIONS

This application claims priority to and the benefit of provisional patent application No. 63/627,763 filed in the United States Patent Office on Jan. 31, 2024, the entire content of this provisional application being incorporated herein by reference as if fully set forth below in its entirety and for all applicable purposes.

### TECHNICAL FIELD

The disclosure relates to fractional frequency division using a multi-modulus divider (MMD) and a digital-to-time converter (DTC). More particularly, this disclosure relates to generating a DTC output that is free of spurious tones related to digitally-controllable delay (DCD) quantization.

### BACKGROUND

Fractional frequency dividers (FFD) are a fundamental component in electronic systems designed to divide the frequency of an input signal by a fractional value. The primary function of an FFD is to generate output frequencies that are non-integer multiples of a given reference frequency. This ability is vital for various applications which require flexible and precise frequency synthesis. FFDs are therefore integral to communication systems and wireless technologies in which the generation of carrier frequencies with high precision is a necessity. Another application of FFDs is in the generation of clock signals used to synchronize the operation of an array of components within a digital system.

A particular application of an FDD is within a Phase-Locked Loop (PLL). The primary function of a PLL is to synchronize the phase of an output signal with the phase of a reference signal. The PLL compares the phases of the input and feedback signals, generating an error signal to adjust the output frequency and phase. The inclusion of an FFD in the PLL provides finer control over the output frequency, enabling the synthesis of frequencies that are non-integer multiples of the reference frequency.

For FFDs using a multi-modulus divider (MMD) that introduces a variable time delay and a digitally-controllable delay (DCD) that modifies said time delay, the difference in resolution between the accumulated quantization error of the MMD controller and DCD input control word is typically resolved by requantization. The process of requantization in the DCD controller within the DTC produces DTC-requantization-related spurious tones in the output spectrum of the DTC. Various methods used and approaches taken to manage the negative effects of DTC-requantization are discussed in this section.

An all-digital phase locked loop (ADPLL) with a multi-modulus divider (MMD) in its feedback path can be used to generate an output frequency that is an integer plus a fraction times a reference frequency, i.e. fout=(Nᵢₙₜ+X/M)fref, where Nᵢₙₜ, X and M are integers. FIG. 1 shows the block diagram of a typical ADPLL, where Nᵢₙₜ, X and M are integers.

The instantaneous divide ratio of the MMD is N_{div}[k]=Nᵢₙₜ+y[k], where y is an integer-valued signal produced by a multi-modulus divider controller. The MMD controller, which is typically based on a digital delta-sigma modulator (DΔΣM), is designed such that the signal y that it produces has an average value of X/M and comprises shaped quantization noise. In this way, fout=(Nᵢₙₜ+X/M)fref, and the shaped quantization noise is filtered by the lowpass transfer function of the loop.

Quantization noise q_{divcon} introduced by the MMD controller is accumulated as a time difference Δt between the edges of the reference and divided signals ref(t) and div(t). When the fractional part of the divide ratio is a non-zero constant, the time difference Δt waveform at the input of the time-to-digital converter (TDC) has a characteristic sawtooth shape, as shown in FIG. 2. The said time difference waveform is correlated with the accumulated quantization noise q_{divcon}^{acc}.

The time difference Δt is measured periodically by the time-to-digital converter (TDC), filtered by the digital loop filter (DLF), and ultimately causes unwanted modulation of the control signal that sets the frequency of the digitally-controlled oscillator (DCO). This unwanted modulation manifests itself in the spectrum as excess phase noise and spurious tones (spurs). FIG. 3 shows simulated phase noise and spurs in the output spectrum of the ADPLL of FIG. 1 that result from MMD controller quantization noise. One way to reduce the unwanted modulation is to bring the edges of the output of the MMD into phase alignment with those of the reference signal at the input of the TDC. In this way, the time difference signal Δt[k] that is measured periodically by the TDC would be approximately constant and so would the control input of the DCO. This can be accomplished in principle by using a digitally-controllable delay (DCD) to delay the edge of the MMD output (or the edge of the reference) by a prescribed amount Δt_{DTC}[k] before applying it to the input of the TDC. The required time delay is related to the accumulated quantization error of the divider controller q_{divcon}^{acc}[k].

FIG. 4A shows an ADPLL with the DTC in series with the MMD in the feedback path, whereby it delays div(t) by an amount Δt_{DTC}[k] to produce the delayed signal div_{D}(t); FIG. 4B shows an ADPLL with the DTC in series with the reference path delaying ref(t) by an amount Δt_{DTC}[k] to produce the delayed signal ref_{D}(t). FIG. 4C shows an ADPLL with the DTC's delay function implemented by two pieces, denoted DTC1 and DTC2, whereby DTC1 in series with the MMD in the feedback path delays div(t) by an amount Δt_{DTC1}[k] to produce the delayed signal div_{D1}(t) and DTC2 in series with the reference path delays ref(t) by an amount Δt_{DTC2}[k] to produce the delayed signal ref_{D2}(t). The three architectures in FIG. 4A, FIG. 4B and FIG. 4C are equivalent in terms of implementing a time shift between the edges of the MMD output and the reference signal. Without loss of generality, we will henceforth refer by default to the configuration in FIG. 4A.

If the quantization error introduced by the MMD were cancelled exactly using the DTC, then the output spectrum would be spur-free, as shown in FIG. 5. Note that the simulated phase noise (gray) follows the theoretical prediction (black dashed).

In practice, the quantized delay introduced by the DTC is required to cancel exactly the uniformly quantized accumulated quantization error. The DTC is a nonlinear mixed-signal component whose transfer characteristic from its input (control word) to its output (delay) exhibits nonlinearity that results in nonlinear distortion and consequently inexact cancellation of the divider controller quantization noise.

FIG. 6 shows the output spectrum when the DCD is nonlinear and suffers from a gain error. This causes the output phase noise spectrum to exhibit an elevated low frequency noise floor and spurs.

At a minimum, it is necessary to calibrate the gain of the DCD controller because an error in this gain will result in incomplete cancellation of the MMD controller's accumulated quantization error, even if the DCD control word to delay input-output transfer characteristic were linear. Digital predistortion can be used to compensate for the nonlinearity of the DCD.

FIGS. 7A and 7B show architectures with gain calibration and digital predistortion (DPD).

The number of discrete levels of the accumulated MMD controller quantization error signal q_{divcon}^{acc} may be larger than the number of delay steps available in the DCD. In this case, the DCD controller must perform a requantization. FIG. 8 shows the output spectrum of the ADPLL of FIG. 4A where ideal gain correction and DPD have been applied. Note that the spectrum contains spurious tones; these result from requantization in the DCD controller.

This problem results from the difference between the number of quantization levels of the MMD controller's accumulated quantization noise q_{divcon}^{acc} and the number of quantization levels of the DCD. In particular, the N_{b}^{DTC}-bit delay introduced by the DTC is required to cancel the N_{b}^{ace}-bit accumulated quantization error, where N_{b}^{DTC}<N_{b}^{acc}. This cannot be realized without introducing a quantization error.

One approach to minimizing nonlinearity-induced spurs resulting from requantization is to use a noise-shaping requantizer, such as a ΔΣ modulator (ΔΣM) instead of a simple quantizer.

FIG. 9 shows a DCD controller containing a first-order ΔΣ modulator to perform the requantization operation.

The ΔΣM scrambles the DCD control word so that it appears noise-like. It does this by pushing the requantization noise to higher frequencies. The reshaped requantization noise appear as excess noise in the output spectrum, as shown in FIG. 10.

The DTC can be implemented with two or more DCDs, as shown in FIG. 11, but this does not solve the requantization problem.

It will be appreciated from FIGS. 8 and 10 that fractional spurs and noise due to requantization in the DTC controller degrade the performance of the overall system in which the fractional divider is being used. This has been found to have a detrimental effect when the system is being used in applications such as communications, radar, and instrumentation. Approaches such as incorporating noise-shaping requantizers replace the unwanted spurs with unwanted noise in the output spectra and so do not solve the problem.

While these examples represent cases where the MMD divider controller receives a constant input, a DTC can be used in combination with an MMD as a fractional divider in more generic cases where the input is time-varying, such as in the case of clocking, communications, radar and signal processing blocks. In these applications too, the presence of nonlinearity may degrade the noise performance with the introduction of spurs and folded noise.

Therefore, in view of the above, there is a need for a method to mitigate DTC-requantization-induced spurs without introducing excessive noise.

### SUMMARY

In one aspect of the present invention, there are various embodiments of a fractional frequency divider consisting of a multi-modulus divider (MMD) and a digital-to-time converter (DTC) comprising a dithered requantizer for mitigating spurs induced by the quantization nonlinearity in a DCD controller are disclosed.

In one embodiment, a dithered requantizer for use in a DCD controller is disclosed, wherein:
the DTC comprises a gain and/or digital predistortion, the dithered requantizer and an N_{b}^{DTC}-bit digitally-controllable delay (DCD), and
the instantaneous divide value of the multi-modulus divider (N_{div}[k]) is determined by the output of the MMD controller, and
the MMD controller produces a signal q_{divcon}^{acc}[k] that is proportional to the accumulated time quantization error introduced by the MMD divider controller, and
the digital gain scales q_{divcon}^{acc}[k] by a gain factor to produce an N_{b}^{ace}-bit signal a[k], wherein:
   the dithered requantizer is configured to combine a discrete-valued dither signal d[k] with a signal s[k] and utilizes a quantizer to requantize said combination to produce c[k], wherein:
   s[k] is generated from a[k], and
   the quantized time delay between the input and output of the N_{b}^{DTC}-bit DCD is defined by the digital gain and c[k].

In one embodiment, the signal s[k] is equal to a[k] and the combination of the dither signal d[k] with s[k] is a simple summation executed by a summer.

In one embodiment, the quantizer which comprises the dithered requantizer is a truncation quantizer, which operates on the summation of a[k] and d[k].

In one embodiment, the quantizer which comprises the dithered requantizer is a rounding quantizer.

In one embodiment, the dither signal d[k] is derived from a random or pseudorandom signal within the system.

In one embodiment, the dither signal d[k] is produced by a random number generator.

In one embodiment, the dither signal d[k] is derived from the quantization error of the MMD controller.

In one embodiment, shown in FIG. 13, the dither signal d[k] is a full-scale uniformly distributed N_{b}^{Δ}-bit random signal produced by a random number generator, where N_{b}^{Δ}=N_{b}^{acc}−N_{b}^{DTC}.

In one embodiment, the dither signal d[k] is an N_{b}^{Δ}+1-bit random number with a triangular probability density function and a range of 2^{N}^{_{b}}^{^{Δ}}⁺¹.

In one embodiment, the dither signal d[k] is a random number with a range larger than 2^{N}^{_{b}}^{^{Δ}}⁺¹.

In an embodiment, the N_{b}^{acc}-bit input signal a[k] is partitioned into two signals s[k] and a_{LO}[k] where a[k]=2^{N}^{_{b}}^{^{Δ}}s[k]+a_{LO}[k], as shown in FIG. 15, wherein:
a_{LO}[k] is applied to the input of a Bernoulli binary generator which produces a one-bit binary output dither signal d[k], and
the Bernoulli binary generator is designed to output d[k]=1 with a probability P where P=a_{LO}[k]/2^{N}^{_{b}}^{^{Δ}}, and d[k]=0 with a probability equal to 1−P, and
d[k] is added to s[k] to produce the output c[k], where

$$c [ k ] = s [ k ] + d [ k ] .$$

In certain embodiments the DCD is partitioned into multiple sections, as shown in FIG. 11 for the case of two sub sections, with DCD1 corresponding to the N_{b}^{DCD1} most significant bits and DCD2 to the N_{b}^{DCD2} next most significant bits of q_{divcon}^{acc} In an embodiment, the N_{b}^{DTC}-bit digitally-controllable delay is partitioned into two digitally-controllable delays DCD1 and DCD2 controlled by N_{b}^{DCD1}-bit and N_{b}^{DCD2}-bit signals c₁[k] and c₂[k] such that N_{b}^{DTC1}+N_{b}^{DTC2}=N_{b}^{DTC}, further comprises:
an N_{b}^{acc} to N_{b}^{DCD1}-bit quantizer which requantizes a[k] to produce c₁[k] and s[k] is combined with d[k] in the dithered requantizer to produce c₂[k], wherein:
the N_{b}^{Δ1}-bit signal s[k] is equal to the quantization error of said N_{b}^{ace} to N_{b}^{DCD1_} bit quantizer and N_{b}^{Δ1}=(N_{b}^{acc}−N_{b}^{DTC1}).

In an embodiment there is provided fractional frequency divider comprising a multi-modulus divider (MMD) and a digital-to-time converter (DTC) in a series connection, wherein:
the DTC comprises a digital gain and/or digital predistortion, a dithered requantizer and a digitally-controllable delay (DCD); and
the dithered requantizer is configured to have an N_{b}^{acc}-bit input signal and an N_{b}^{DTC}-bit output signal, and combine a discrete-valued dither signal d[k] with a digital signal s[k], and utilize a quantizer to requantize said combination to produce an output digital signal c[k] which is applied to the control input of the DCD, wherein:
the digital signal s[k] is generated from a digital signal a[k], where a[k] is a combination of an output signal of the MMD controller and the digital predistortion, and
the quantized time delay between the input and output of the DCD applied to mitigate requantization-related spurious tones in the output signal of the DTC is defined by the digital distortion and the output signal c[k].

In an embodiment there is provided a fractional frequency divider comprising a digital-to-time converter (DTC) wherein the DTC comprises a digital predistortion, a dithered requantizer and a digitally-controllable delay (DCD); the dithered requantizer is configured to combine a discrete-valued dither signal d[k] with a digital signal s[k], and utilize a quantizer to requantize said combination to produce an output digital signal c[k] which is applied to the control input of the DCD.

In an embodiment the digital signal s[k] is generated from a digital signal a[k], where a[k] is a combination of an output signal from a multi-modulus divider (MMD) controller and the digital predistortion associated with the fractional frequency divider.

In an embodiment, the quantization error cancellation function of the DTC can be implemented by inserting the DTC between the MMD output and the div input of the TDC (the “div” path) as shown in FIG. 4A, or between the reference input and the ref input of the TDC (the “ref” path) as shown in FIG. 4B.

In an embodiment, the DTC function is implemented using two DCDs, DCD1 and DCD2 which can be connected in series to form a single effective DTC, as shown in FIG. 11, and inserted in the div or ref paths, as shown in FIG. 4A and FIG. 4B.

In an embodiment, the MMD and DCD1 are connected in cascade in the feedback path and DCD2 is in the reference path, shown in FIG. 4C.

In another aspect of the present invention there is provided a method for suppressing spurious tones in digitally-controllable delay (DCD) systems, the method comprising: generating an accumulated time quantization error signal from a timing signal component, wherein a resolution mismatch between the output of the timing signal component and the quantization levels of the DCD results in a quantization error; scaling the accumulated quantization error signal using a gain and/or digital predistortion to match the DCD input range; combining the scaled signal with a discrete-valued dither signal in a dithered requantizer; requantizing the combined signal in the dithered requantizer to produce a control signal; and applying the control signal to the DCD to generate a quantized time delay.

In an embodiment of the method of for suppressing spurious tones the timing signal component is a multi-modulus divider (MMD) controller.

In another aspect of the present invention, there is provided a method for suppressing spurious tones in a fractional frequency divider comprising a multi-modulus divider (MMD) and a digitally-controllable delay (DCD), the method comprising the steps of:
producing an accumulated time quantization error signal from an MMD controller; scaling the quantization error signal using a gain and/or digital predistortion; combining the scaled signal with a discrete-valued dither signal in a dithered requantizer; requantizing the combined signal to produce a control signal; and applying the control signal to the digitally-controllable delay (DCD) to generate a quantized time delay.

In another aspect of the present invention there is provided a fractional frequency divider comprising: a multi-modulus divider (MMD),, wherein an MMD controller is configured to generate an accumulated time quantization error signal; a gain and/or digital predistortion module configured to scale the accumulated quantization error signal; a dithered requantizer configured to combine the scaled signal with a discrete-valued dither signal and requantize the combined signal to produce a control signal; and a digitally-controllable delay (DCD) configured to receive the control signal from the dithered requantizer and generate a quantized time delay that suppresses spurious tones.

### BRIEF DESCRIPTION OF THE DRAWINGS

The present disclosure will be more clearly understood from the following description of an embodiment thereof, given by way of example only, with reference to the accompanying drawings, in which:

FIG. 1 shows the block diagram of a conventional all digital phase locked loop with a multi-modulus divider in the feedback path.

FIG. 2A shows simulated waveforms in an ADPLL when implementing fractional division by

$$3 + \frac{1}{4} .$$

FIG. 2B shows the simulated time difference between the edges of the ref and div signals signal at the input to the time-to-digital converter, and the accumulated quantization error of the multi-modulus divider.

FIG. 3 shows the spectrum of the output phase noise of the ADPLL in FIG. 1;

FIG. 4A shows a block diagram of an all-digital phase locked loop with a multi-modulus divider and a digital-to-time converter together implementing fractional division in the feedback path;

FIG. 4B shows a block diagram of an all-digital phase locked loop with a multi-modulus divider in the feedback path and a digital-to-time converter in the reference path together implementing fractional division;

FIG. 4C shows a block diagram of an all-digital phase locked loop with a multi-modulus divider in the feedback path and digital-to-time converters in the feedback and reference paths that together implement fractional division;

FIG. 5 shows the spectrum of the output phase noise of the all-digital PLL in FIG. 4A when the DTC cancels the quantization error introduced by the multi-modulus divider exactly;

FIG. 6 shows the spectrum of the output phase noise of the all-digital PLL in FIG. 4A when the DTC exhibits gain and nonlinearity errors and therefore does not cancel the quantization error introduced by the multi-modulus divider exactly;

FIG. 7A shows a block diagram of a DTC comprising programmable digital gain, a requantizer and a digitally-controllable delay;

FIG. 7B shows a block diagram of a DTC comprising programmable digital predistortion, a requantizer and a digitally-controllable delay;

FIG. 8 shows the spectrum of the output phase noise of the all-digital PLL in FIG. 4A when the gain and nonlinearity errors of the DTC have been corrected using programmable digital gain and/or digital predistortion and its only residual nonlinearity is that due to requantization;

FIG. 9 shows a block diagram of a DTC comprising programmable digital gain and/or predistortion, a requantizer implemented as a digital ΔΣ modulator, and a digitally-controllable delay;

FIG. 10 shows the spectrum of the output phase noise of the all-digital PLL in FIG. 4A when the gain and nonlinearity errors of the DTC have been corrected using programmable digital gain and/or digital predistortion and the requantizer has been implemented as a digital ΔΣ modulator;

FIG. 11 shows a block diagram of a partitioned DTC comprising two digitally-controllable delays. Each digitally-controllable delay has a DCD controller which contains a requantizer. The second DCD is controlled by the error of the first requantizer;

FIG. 12 shows a DTC containing a dithered requantizer that is the subject of this disclosure;

FIG. 13 shows a first embodiment of a dithered requantizer comprising a random number generator, an adder and a truncation quantizer;

FIG. 14A shows the graph of the output versus the input of a requantizer without dither;

FIG. 14B shows the graph of the averaged output versus the input of a dithered requantizer;

FIG. 15 shows a second embodiment of a dithered requantizer comprising a bus splitter, a Bernoulli binary generator and an adder.

FIG. 16A shows the power spectra of the signals q_{divcon}^{acc} and c in a DCD controller using the undithered requantizer with the input-output transfer characteristic of FIG. 14A;

FIG. 16B shows the power spectra of the signals q_{divcon}^{acc} and c in a DCD controller using the dithered requantizer of FIG. 14B;

FIG. 17A shows the power spectra of the DTC's residual error after cancelling the accumulated quantization error of the MMD controller of FIG. 4A with a DCD controller using an undithered requantizer;

FIG. 17B shows the power spectra of the DTC's residual error after cancelling the accumulated quantization error of the MMD controller of FIG. 4A with a DCD controller using the dithered requantizer of this disclosure;

FIG. 18A shows the power spectra of the output phase noise of the ADPLL of FIG. 4A with a DCD controller using an undithered requantizer; and

FIG. 18B shows the power spectra of the output phase noise of the ADPLL of FIG. 4A with a DCD controller using the dithered requantizer of this disclosure.

### DETAILED DESCRIPTION

The present disclosure provides a dithered requantizer for a digitally-controllable delay that, among other applications, is suitable for use in series with a multi-modulus divider as an open-loop feedforward fractional divider or as a closed-loop feedback divider in a digital-intensive PLL-based fractional-N frequency synthesizer.

When used in a DCD controller, the dithered requantizer eliminates the spurs that would otherwise arise due to resolution mismatch between the accumulated quantization error introduced by the MMD and the quantization levels of the DCD.

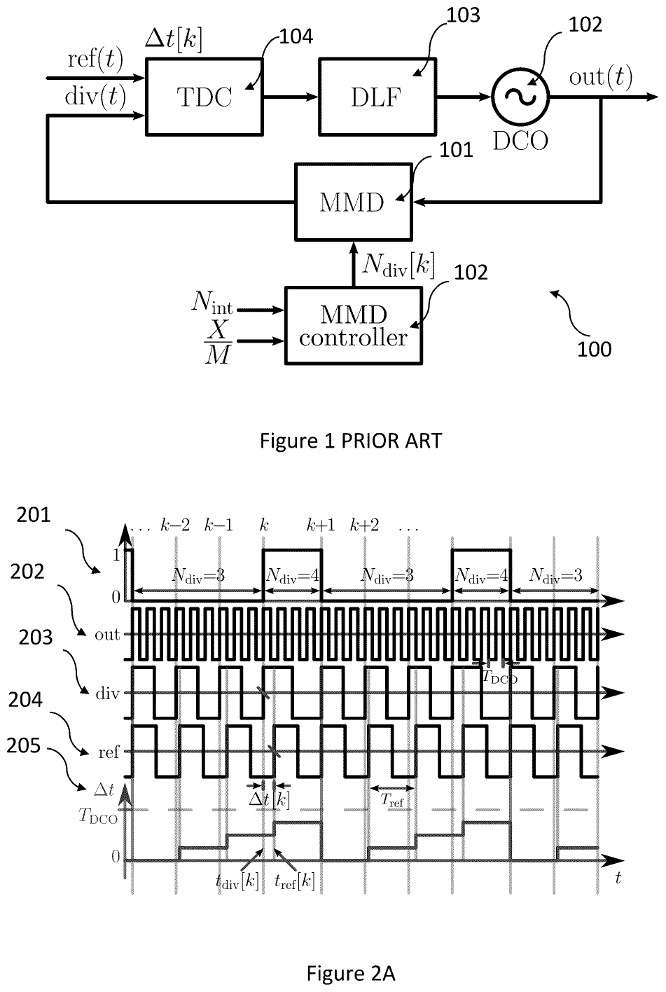

FIG. 1 shows an ADPLL 100 which contains a multi-modulus divider (MMD) 100 in the feedback path, also including a time-to-digital converter (TDC) 104, a digital loop filter (DLF) 103, a digitally controlled oscillator (DCO) 102, which is dithered by an MMD controller 102 to accomplish fractional frequency division.

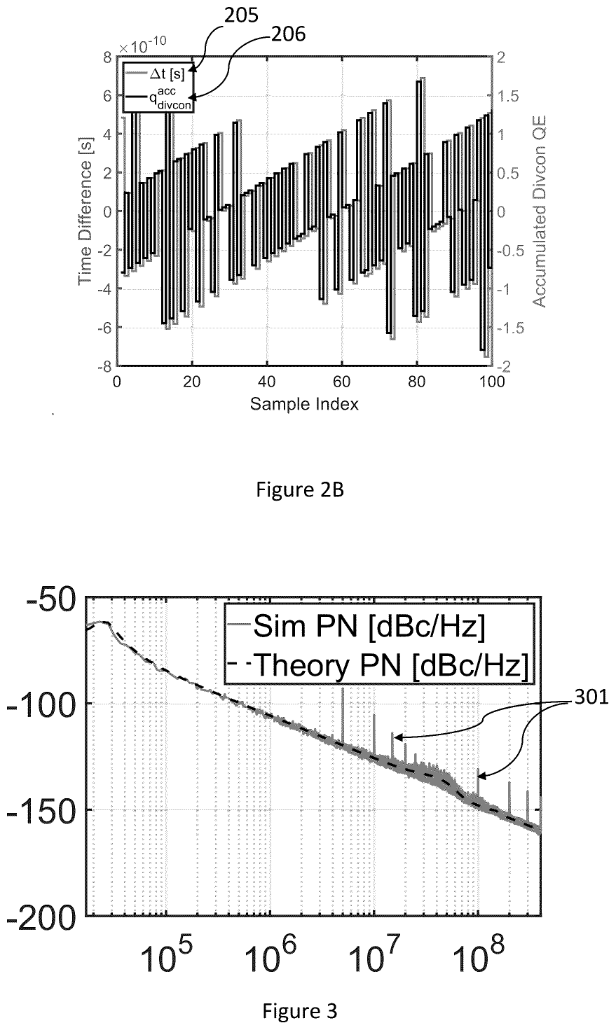

FIG. 2A illustrates how an output frequency

$${f}_{out} = ( {N}_{int} + \frac{X}{M} ) {f}_{ref} ,$$

can be realized in the case Nᵢₙₜ=3, X=1 and M=4. In this example, the division ratio N_{div} of the MMD 101 is varied by the MMD controller 102 between the values 3 and 4 to realize division by

$$3 + \frac{1}{4} .$$

The top row of FIG. 2A shows the divide ration N_{div} 201, which takes the value N_{div}=3 for three cycles of the reference clock ref(fourth row) in every four and the value N_{div}=4 for one cycle in four, leading to an average value

$$E \{ {N}_{div} \} = 3 + \frac{1}{4} ,$$

where E {·} denotes the expectation operator. The output signal out 202 (second row) has a frequency

$${f}_{out} = ( 3 + \frac{1}{4} ) {f}_{ref} ,$$

Due to the changing division ratio N_{div}, the rising edges of the MMD output signal div 203 (third row) are displaced in time relative to the edges of ref. This leads to a varying time difference signal Δt 205, being the difference between the rising edges of the div and ref signals at the input to the time-to-digital converter (TDC).

FIG. 2B shows how the signal Δt 205 is strongly correlated with the accumulated quantization error q_{divcon}^{acc} 206 of the divider (MMD) controller 102.

FIG. 3 shows the presence of spurious tones 301 in the spectrum of the output signal of the PLL in FIG. 1 for an example wherein the MMD controller 102 is a third-order digital ΔΣ modulator. The time difference signal Δt 205 has a characteristic sawtooth shape with apparently random jumps. The accumulated quantization error of the MMD controller 102, q_{divcon}^{acc} 206 matches the time difference signal that causes unwanted modulation of the DCO and spurious tones 301.

This suggests that using q_{divcon}^{acc} ac 206 to control a delay in a DTC can zero the time difference applied at the input of the TDC.

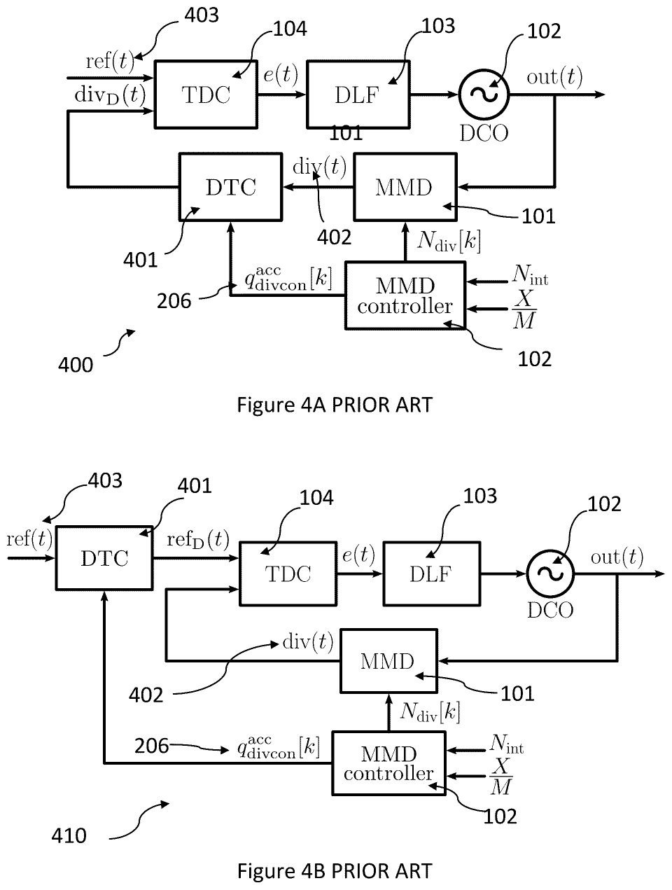

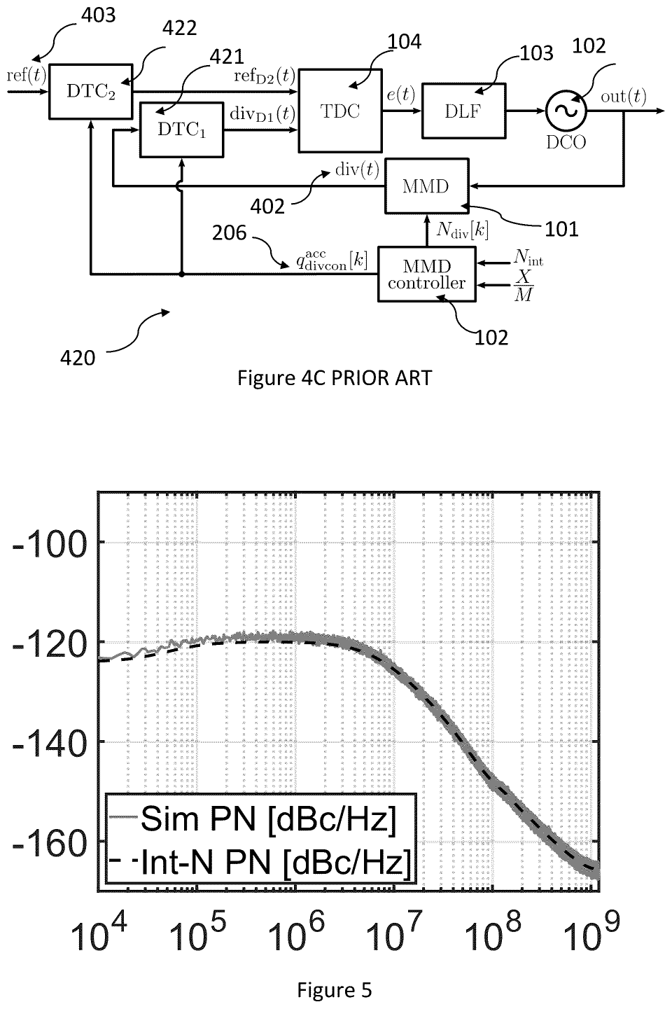

FIG. 4A shows a block diagram of an all-digital phase locked loop 400 with a multi-modulus divider 101 and a digital-to-time converter 401 together implementing fractional division in the feedback path.

FIG. 4B shows a block diagram of an all-digital phase locked loop 410 with a multi-modulus divider 101 in the feedback path and a digital-to-time converter 401 in the reference path together implementing fractional division.

FIG. 4C shows a block diagram of an all-digital phase locked loop 420 with a multi-modulus divider 101 in the feedback path and digital-to-time converters 421, 422 in the feedback and reference paths that together implement fractional division.

The signal q_{divcon}^{acc} 206 can be used to control a digital-to-time converter 401, 421, 422, denoted DTC 401 in FIG. 4A, that delays the div(t) 402 signal from the MMD 101 output by an amount that brings the edges of div 203 and ref 204 into alignment and nominally zeroes Δt 205. Zeroing can be effected by delaying div(t) 402 and/or ref(t) 403, as shown in FIG. 4A, FIG. 4B, and FIG. 4C.

FIG. 5 shows that if Δt 205 could be zeroed exactly, then the envelope of the output phase noise power spectrum of the fractional-N ADPLL could match that of its integer-N counterpart. In practice, q_{divcon}^{acc} 206 is an N_{b}^{divcon}-bit signal having 2^{N}^{_{b}}^{^{divcon}} levels, while the digitally-controllable delay in the DTC 401 has just 2^{N}^{_{b}}^{^{DTC}} where N_{b}^{DTC}<N_{b}^{divcon}. Due to the resolution mismatch between the accumulated quantization error signal q_{divcon}^{acc} 206 and the control signal c applied to the DCD, it is not possible to zero Δt 205.

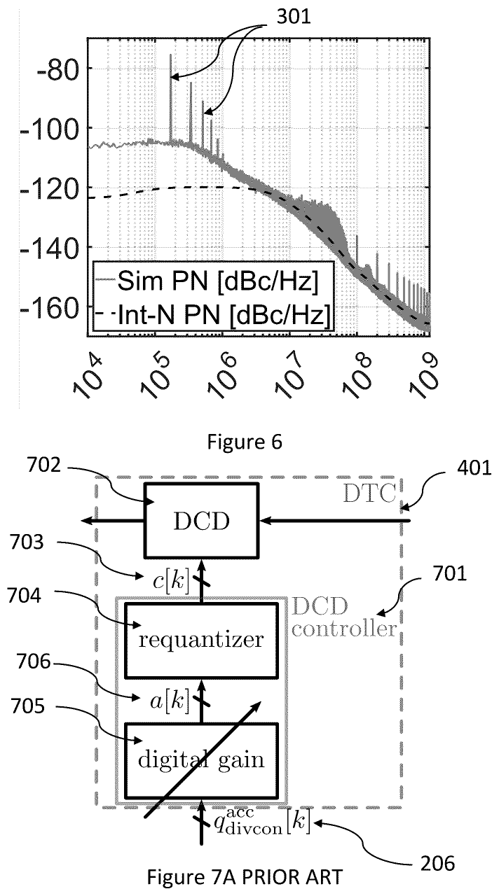

FIG. 6 shows the excess noise and spurious tones of the output phase noise power spectrum of the fractional-N ADPLL 301 which differs significantly from that of its integer-N counterpart.

In addition to the requantization problem, the DTC 401 is typically nonlinear and a gain factor is required between the accumulated quantization error signal q_{divcon}^{acc} 206 and the control signal c.

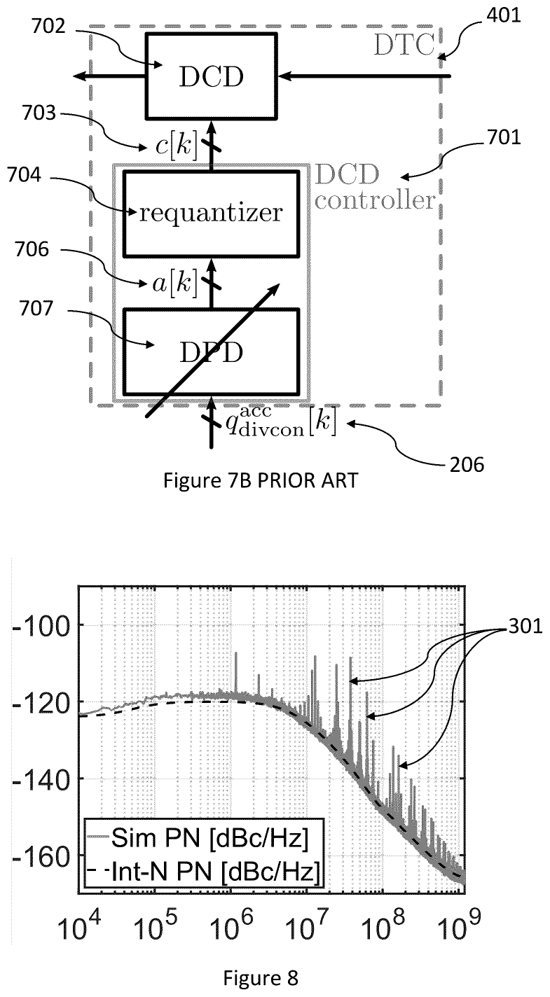

FIGS. 7A and 7B show constructions in which gain and nonlinearity correction can be accomplished implementing a programmable gain 705 and/or digital predistortion 707 function between the input to the DCD controller 701 q_{divcon}^{acc} 206 and the input a 706 to the DCD controller's requantizer 704. While these can reduce the excess noise, they cannot remove the spurs 301 that result from requantization in the DCD controller 701.

FIG. 8 shows that the envelope of the output phase noise power spectrum is closer to its integer-N counterpart but it contains spurs 301 resulting from requantization.

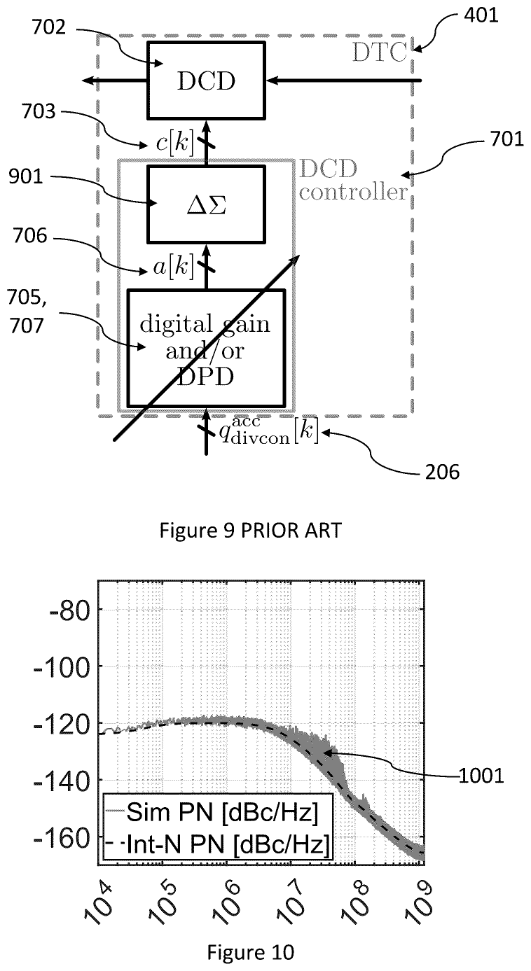

FIG. 9 shows one approach to mitigating requantization-induced spurs which is to use a digital ΔΣ modulator 901 to perform the requantization between a 706 and c 703. While this approach succeeds in mitigating the requantization-induced spurs, the digital ΔΣ modulator 901 introduces excess noise.

FIG. 10 shows the spectrum of the output phase noise of the all-digital PLL in FIG. 4A when the gain and nonlinearity errors of the DTC have been corrected using programmable digital gain 705 and/or digital predistortion 706 and the requantizer has been implemented as a digital ΔΣ modulator 901 as in FIG. 9—in this case the spectrum is spur-free but the envelope of the noise 1001 lies above the theoretically achievable performance limit.

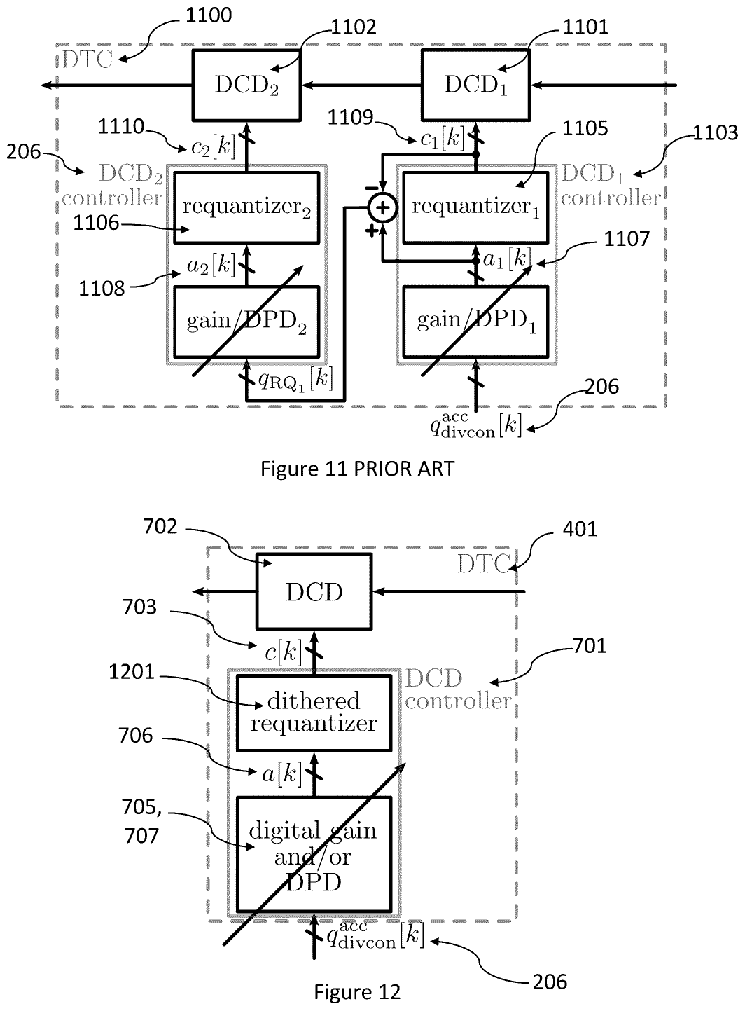

FIG. 11 shows a block diagram of a partitioned DTC 1100 comprising two digitally-controllable delays 1101, 1102. The realignment of the ref and div edges can also be accomplished by partitioning the DCD into two digitally-controllable delays, DCD1 1101 and DCD2 1102, that are used to delay one or both of ref(t) and div(t). When the DCD function is partitioned between a coarse delay DCD1 1101 and a fine delay DCD2 1102, the signal q_{divcon}^{acc} 206 is applied as input to the DCD1 controller 1103 controlling the coarse DCD1 1101, and the quantization error of the coarse requantizer is applied as input to the DCD2 controller 1104 controlling the fine DCD2 1102, as shown in FIG. 11. The architecture in FIG. 11 suffers from the same requantization problem as FIG. 4A and FIG. 4B, even when one or more of the requantizers 1105, 1106 is implemented as a digital ΔΣ modulator.

The present disclosure of a dithered requantizer solves the problem of requantization-induced spurs in the DTC and will now be described in conjunction with FIG. 12 onwards.

A conventional DTC 401 comprises a digitally-controllable delay (DCD) 702 and a DCD controller 701. The DCD 702 has a signal input 703, a control input, and a signal output. The N_{b}DTC-bit digital word c 703 applied to the control input sets the quantized time delay between the signal input and the signal output.

The DCD controller 701 takes as input an N_{b}^{divcon}-bit digital word q_{divcon}^{acc} 206 corresponding to the accumulated quantization error of a multi-modulus divider controller 102 and outputs the N_{b}^{DTC}-bit digital word c that is applied to the control input 703 of the DCD 702.

The DCD controller 701 performs two functions: it applies gain and/or digital predistortion 705, 706 to the input signal q_{divcon}^{acc} 206 yielding an intermediate signal N_{b}^{acc}-bit signal a 706, and then requantizes the signal a 706 before outputting the N_{b}^{DTC}-bit digital word c 703.

The dithered requantizer 1201 for use in a DCD controller 701 has an N_{b}^{ace}-bit input signal a[k] 706, an N_{b}^{DTC}-bit output signal c[k] 703, an N_{b}^{Δ}-bit quantizer, where N_{b}^{Δ}=N_{b}^{acc}−N_{b}^{DTC}, and an additive dither signal d[k] 1301, where the average value of the signal c[k] 703 equals a constant plus the input signal a[k] 706, scaled by ½^{N}_{b}^{Δ}.

FIG. 12 shows an embodiment 1200 in which a dithered requantizer 1201 is implemented within a DCD controller 701 wherein the input-output relation of the dithered requantizer 1201 in the DCD controller 701 is described by the equation:

$$c [ k ] = Q ( a [ k ] + d [ k ] ) ,$$

where Q(·) denotes quantization from N_{b}^{acc} bits to N_{b}^{DTC} bits, and

$$c [ k ] = \frac{a [ k ]}{{2}^{{N}_{b}^{Δ}}} + r q [ k ]$$

where rq is a random number,

$$E \{ c \} = \frac{a}{{2}^{{N}_{b}^{Δ}}} + r {q}_{os} ,$$

E{·} denotes the expectation operator, and where rqₒₛ is a constant.

In the Z domain, C(z)=STF(z)A(z)+RQ(z) where A(z), C(z) and D(z) are the Z transforms of a[k] 706, c[k] 703, and d[k] 1301, respectively, STF(z) is a scaling factor and RQ(z) is the Z transform of rq[k].

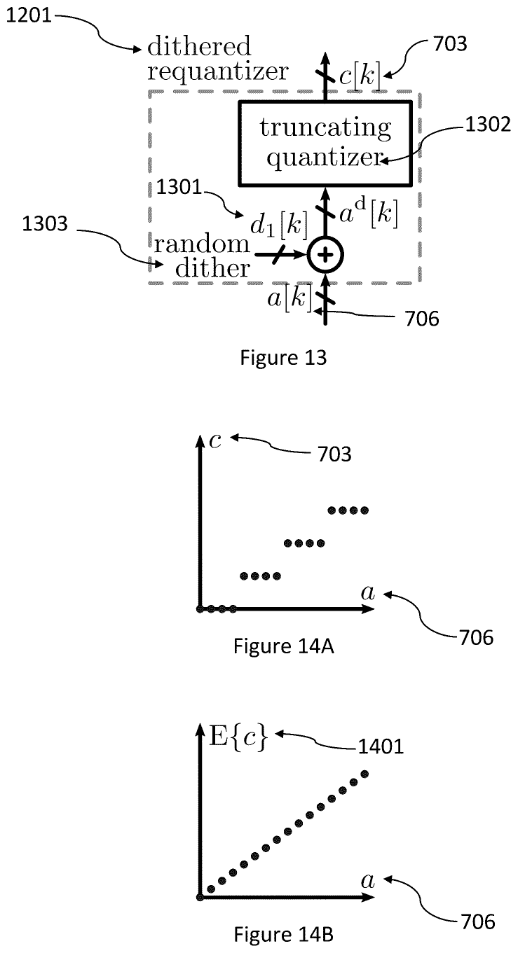

FIG. 13 shows an implementation in which the dither signal is a full-scale uniformly distributed N_{b}^{Δ}-bit random signal 1301 d[k]=d₁[k] produced by a random number generator 1303, where N_{b}^{Δ}=N_{b}^{acc}−N_{b}^{DTC}, and Q(·) is a truncation quantizer 1302.

FIG. 14A and FIG. 14B show representative graphs of c 703 and E {c} 1401, respectively, versus a 706. While FIG. 14A has a staircase structure due to the resolution mismatch between a 706 and c 703, the averaged DCD control signal E {c} 1401 in FIG. 14B is linearly related to a 706.

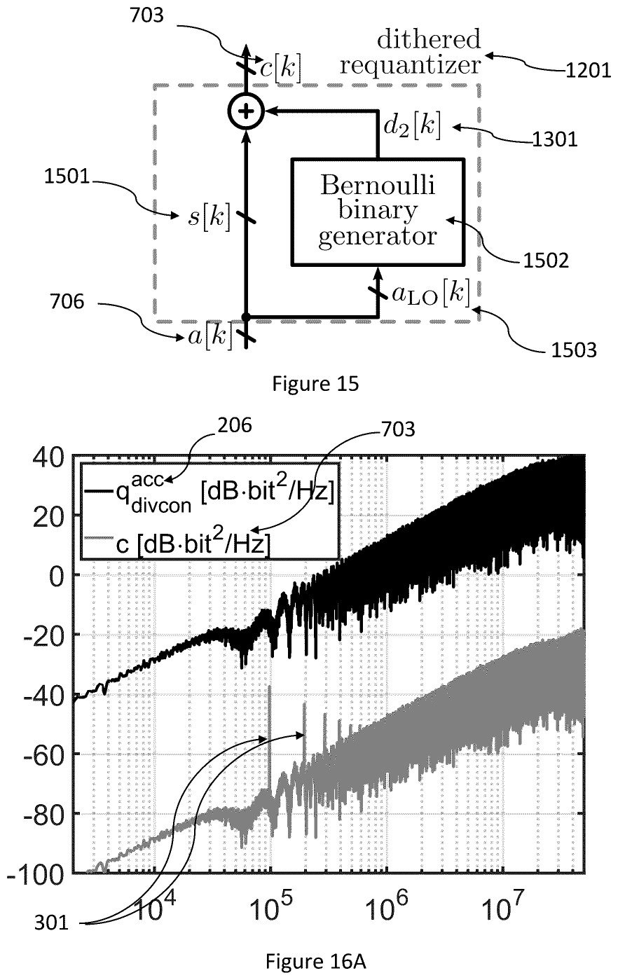

FIG. 15 shows an implementation in which the dithered requantizer, N_{b}^{acc}-bit input signal a[k] 706 is partitioned into two signals s[k] 1501 and a_{LO}[k] 1503 where a[k]=2^{N}^{_{b}}^{^{Δ}}s[k]+a_{LO}[k].

a_{LO}[k] 1503 is applied to the input of a Bernoulli binary generator 1502 which produces a one-bit binary output dither signal 1301 d[k]=d₂[k]. The Bernoulli binary generator 1502 is designed to output d[k]=1 with a probability P where P=a_{LO}[k]/2^{N}^{_{b}}^{^{Δ}}, and d[k]=0 with a probability equal to 1-P·d[k] 1301 is added to s[k] 1501 to produce the output c[k] 703, where:

$$c [ k ] = s [ k ] + d [ k ]$$

Here too,

$$c [ k ] = \frac{a [ k ]}{{2}^{{N}_{b}^{Δ}}} + rq [ k ]$$

where rq is a random number,

$$E \{ c \} = \frac{a}{{2}^{{N}_{b}^{Δ}}} + {rq}_{os} ,$$

E and rqₒₛ is a constant.

In the case where the DCD 702 is partitioned into coarse and fine sections, as shown in FIG. 11, with DCD1 1101 corresponding to the N_{b}^{DCD1} most significant bits and DCD2 1102 to the N_{b}^{DCD2} next most significant bits of q_{divcon}^{acc} 206, a first requantizer, denoted requantizer₁ 1105 in FIG. 11, is used to quantize the N_{b}^{acc}-bit signal a₁ 1107 to produce the N_{b}^{DCD1}-bit control signal c₁ 1109 that controls DCD1 1101.

The quantization error signal q_{RQ1} of the first requantizer 1105, being the difference between a[k] 706 and c₁[k] 703, is applied to the input of the second DCD controller 1104. The requantizer in the second DCD controller, denoted requantizer₂ 1106 in FIG. 11, is a dithered requantizer, and is implemented as shown in FIG. 13 or FIG. 15.

The quantization error cancellation function of the DTC 401 can be implemented by inserting the DTC 401 between the MMD output 202 and the div input 203 of the TDC 104 (the “div” path), as shown in FIG. 4A, between the reference input and the ref input of the TDC (the “ref” path), as shown in FIG. 4B, or by inserting two DTCs, one in the div path and the other in the ref path, as shown in FIG. 4C.

When the DTC 401 function is implemented using two DCDs, denoted DCD1 1101 and DCD2 1102, as described above, in one implementation, DCD1 1101 and DCD2 1102 can be connected in series to form a single effective DTC, as shown in FIG. 11, and inserted in the div or ref paths, as shown in FIG. 4A and FIG. 4B. In another implementation, DCD1 1101 could be inserted in the div path and DCD2 1102 in the ref path, as shown in FIG. 4C.

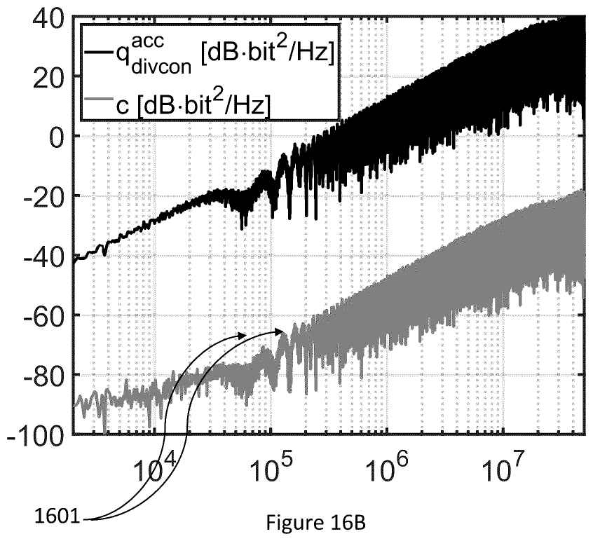

FIG. 16A shows the power spectra of q_{divcon}^{acc} 206 and c 703 when a conventional undithered quantizer with the input-output characteristic of FIG. 14A is employed. Ideally, the spectrum of c 703 should be a scaled version of the spectrum of q_{divcon}^{acc} 206. Due to quantization in the DCD controller 701, the spectrum of c[k] 703 also contains spurs 301. By contrast, FIG. 16B shows that the power spectrum of c[k] 703 is spur-free 1601 in the case of the dithered requantizer 1201 of FIG. 13.

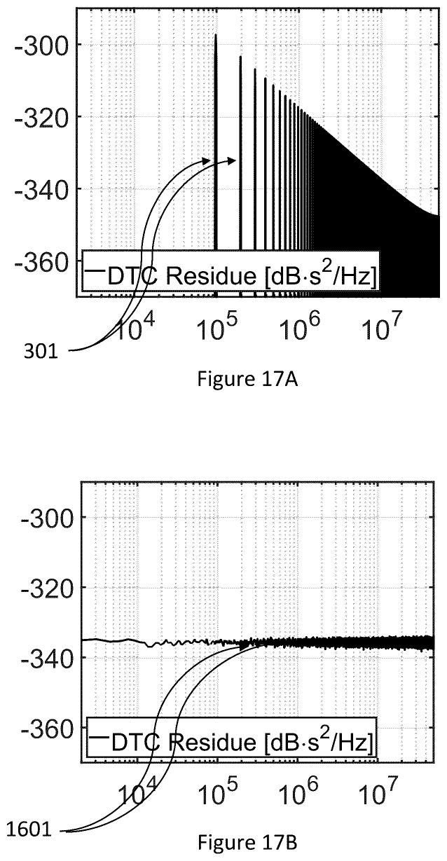

FIG. 17A shows the spectrum of the residual error after cancellation of the MMD's timing error by the DTC 401 with a conventional undithered quantizer 704 in its DCD controller 701. The spectrum contains many spurs 301. By contrast, the spectrum of the residual error after cancellation by the DTC 401 with a dithered quantizer 1201 in its DCD controller 701 is spur-free 1601, as shown in FIG. 17B.

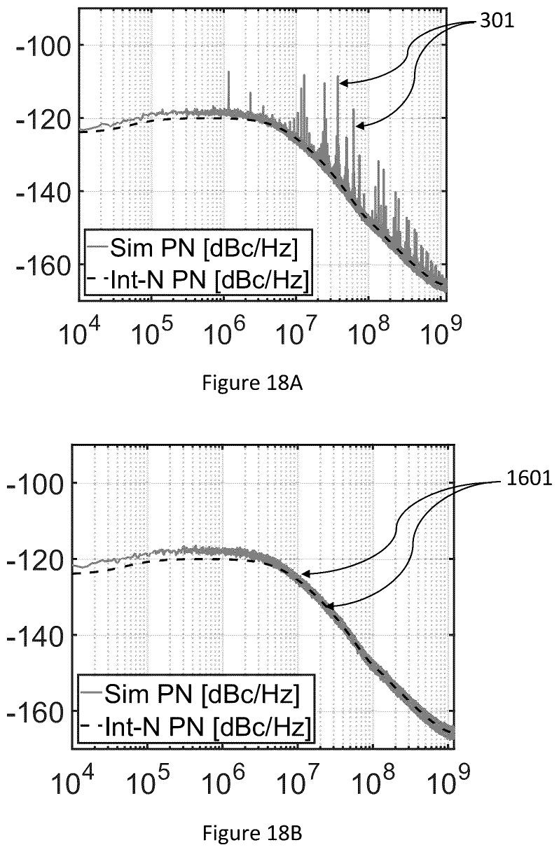

FIG. 18A and FIG. 18B show the output phase noise spectra of ADPLLs with DTCs 401 having undithered 704 and dithered 1201 requantizers, respectively. The undithered requantizer 704 produces requantization-induced spurs 301 in the spectrum, while the dithered requantizer 1201 does not.

In the specification the terms “comprise, comprises, comprised and comprising” or any variation thereof and the terms include, includes, included and including” or any variation thereof are considered to be totally interchangeable, and they should all be afforded the widest possible interpretation and vice versa.

The invention is not limited to the embodiments hereinbefore described but may be varied in both construction and detail.

What is claimed is:

1. A fractional frequency divider comprising a multi-modulus divider (MMD) and a digital-to-time converter (DTC) in a series connection, wherein:
the DTC comprises a gain and/or digital predistortion, a dithered requantizer and an N_{b}^{DTC}-bit digitally-controllable delay (DCD); and
an instantaneous divide value of the MMD is determined by the output of an MMD controller, wherein:
the MMD controller produces a signal q_{divcon}^{acc}[k] that is proportional to an accumulated time quantization error introduced by the MMD controller; and
a digital gain scales q_{divcon}^{acc}[k] by a gain factor to produce an N_{b}^{acc}-bit signal a[k], wherein:
the dithered requantizer is configured to combine a discrete-valued dither signal d[k] with a signal s[k] and utilizes a quantizer to requantize said combination to produce an output signal c[k], and the output c[k] of the dithered requantizer is applied to the control input of the DCD.

2. The fractional frequency divider of claim 1, wherein s[k] is generated from a[k], and the quantized time delay between the input and output of the N_{b}^{DTC}-bit DCD is defined by the output signal c[k].

3. The fractional frequency divider of claim 1 wherein s[k] is equal to a[k] and the combination of d[k] with a[k] is executed by a summer.

4. The fractional frequency divider of claim 3, wherein the quantizer is a truncating quantizer.

5. The fractional frequency divider of claim 3, wherein the quantizer is a rounding quantizer.

6. The fractional frequency divider of claim 3, wherein the dither signal d[k] is derived from a random or pseudorandom signal within the system.

7. The fractional frequency divider of claim 3, wherein the dither signal d[k] is produced by a random number generator.

8. The fractional frequency divider of claim 3, wherein the dither signal d[k] is derived from the quantization error of the MMD controller.

9. The fractional frequency divider of claim 3 wherein the dither signal d[k] is a full-scale uniformly-distributed N_{b}^{Δ}-bit random number, where N_{b}^{Δ}=(N_{b}^{acc}−N_{b}^{DTC}).

10. The fractional frequency divider of claim 3 wherein the dither signal d[k] is an N_{b}^{Δ}+1-bit random number with a triangular probability density function and a range of 2^{N}^{_{b}}^{^{Δ}}⁺¹.

11. The fractional frequency divider of claim 3 wherein the dither signal d[k] is a random number with a range larger than 2^{N}^{_{b}}^{^{Δ}}⁺¹.

12. The fractional frequency divider of claim 1, wherein:
the dithered requantizer further comprises a Bernoulli binary generator and an N_{b}^{acc}-bit to N_{b}^{DTC}-bit truncating quantizer, and the N_{b}^{acc}-bit input signal a[k] is partitioned into two parts s[k] and a_{LO}[k], where a[k]=2^{N}^{_{b}}^{^{Δ}}s[k]+a_{LO}[k]; and
d[k] is added to s[k] to produce the output c[k]=s[k]+d[k], wherein d[k] is a one-bit binary output dither signal produced by a Bernoulli binary generator, such that d[k]=1 with probability P and d[k]=0 with probability (1-P), where P=a_{LO}[k]/2^{N}^{_{b}}^{^{Δ}}.

13. The fractional frequency divider of claim 1 wherein:
the N_{b}^{DTC}-bit DCD is further partitioned into two digitally-controllable delays DCD1 and DCD2 controlled by N_{b}^{DCD1}-bit and N_{b}^{DCD2}-bit signals c₁[k] and c₂[k] such that N_{b}^{DTC1}+N_{b}^{DTC2}=N_{b}^{DTC}, further comprising an N_{b}^{acc} to N_{b}^{DCD1}-bit quantizer which requantizes a[k] to produce c₁[k]; and
s[k] is combined with d[k] in the dithered requantizer to produce c₂[k], wherein the N_{b}^{Δ1}-bit signal s[k] is equal to the quantization error of said N_{b}^{ace} to N_{b}^{DCD1}-bit quantizer and N_{b}^{Δ1}=N_{b}^{acc}−N_{b}^{DTC1}.

14. The fractional frequency divider of claim 13, wherein the fractional frequency divider is included in a phase-locked loop, wherein the MMD and DCD1 are connected in cascade in a feedback path of the phase-locked loop, and wherein the DCD2 is included in a reference path of the phase-locked loop.

15. The fractional frequency divider of claim 13, wherein the fractional frequency divider is included in a phase-locked loop, wherein DCD1 and DCD2 are connected in series to form a single effective DTC that is configured for inclusion in a reference path or divider path of the phase-locked loop.

16. The fractional frequency divider of claim 1, wherein the fractional frequency divider is included in a feedback path of a phase-locked loop.

17. The fractional frequency divider of claim 1, wherein the fractional frequency divider is included in a phase-locked loop, and wherein the DTC is included in a reference path of the phase-locked loop.

18. A method for suppressing spurious tones in digitally-controllable delay DCD systems, the method comprising:
generating an accumulated time quantization error signal from a timing signal component, wherein a resolution mismatch between the output of the timing signal component and the quantization levels of the DCD results in a quantization error;
scaling the accumulated quantization error signal using a gain and/or digital predistortion to match the DCD input range;
combining the scaled signal with a discrete-valued dither signal in a dithered requantizer;
requantizing the combined signal in the dithered requantizer to produce a control signal; and
applying the control signal to the DCD to generate a quantized time delay.

19. The method of claim 18, wherein the timing signal component is a multi-modulus divider MMD.

20. A fractional frequency divider comprising:
a multi-modulus divider MMD, wherein an MMD controller is configured to generate an accumulated time quantization error signal;
a gain and/or digital predistortion module configured to scale the accumulated quantization error signal;
a dithered requantizer configured to combine the scaled signal with a discrete-valued dither signal and requantize the combined signal to produce a control signal; and
a digitally-controllable delay DCD configured to receive the control signal from the dithered requantizer and generate a quantized time delay that suppresses spurious tones.
